(19) United States
(12) Patent Application Publication
(10) Pub. No.: US 2015/0201496 A1
(43) Pub. Date: Jul. 16, 2015

(54) RADIO MODULE AND RELEVANT MANUFACTURING METHOD

(71) Applicants: Jichang Liao, Beijing (CN); Ning Sun, Beijing (CN)

(72) Inventors: Jichang Liao, Beijing (CN); Ning Sun, Beijing (CN)

(73) Assignee: Telefonaktiebolaget L M Ericsson (publ), STOCKHOLM (SE)

(21) Appl. No.: 14/419,979

(22) PCT Filed: Aug. 10, 2012
(86) PCT No.: PCT/CN2012/079979

§ 371 Date: Feb. 6, 2015

(51) Int. Cl. H05K 1/14; H05K 9/00; H05K 1/02

(52) U.S. Cl. CPC H05K 1/144; H05K 1/0203; H05K 9/00; H05K 2201/10734

(57) ABSTRACT

A radio module comprises a top board (110) with all components mounted on a front surface (111) and a metal substrate on a back surface (112); a bottom board (120) with all components mounted on a front surface (121) and a metal substrate on a back surface (122), wherein the bottom board (120) is arranged so that the front surface (121) of the bottom board (120) is opposite to the front surface (111) of the top board (110); and at least one shielding board (130) provided between the top board (110) and the boom board (120) with certain vertical spacing. The top board (110), the bottom board (120), and the at least one shielding board (130) are arranged to be substantially in alignment in a vertical direction and be fastened with one another. A board-board electrical connection (140-1, 140-2) is established at least between the top board (110) and the bottom board (120).

### TECHNICAL FIELD

The embodiments of the present invention generally relate to printed circuit boards (PCBs), particularly to radio modules operatively connected with a main board.

### DESCRIPTION OF THE RELATED ART

Single-side mounted radio boards and double-side mounted radio boards are widely adopted in almost all today's radio unit.

Typically, a single-side mounted PCB, which has all its components mounted on its front surface and has a metal substrate formed on its back surface, can provide more effective grounding and cooling performance. A double-side mounted PCB, which has its components mounted on both its front and back surfaces, typically offers a relatively small PCB size and board dimension. Here, the components of PCBs as mentioned above may include active and passive elements such as resistors, capacitor, inductors, transformers, filters, mechanical switches, relays and so on.

For a radio PCB, in order to get very good reference for micro-strip for radio energy transmission, good grounding connection is very important. Since the active elements will generate a lot of heat, good connection between the board and cooling mechanical parts is also needed for heat dissipation. Further, in order to fulfill electromagnetic compatibility (EMC) requirements, a separate metal EMC cover above the component-mounted surface of a board is needed for shielding.

However, existing solutions of radio boards have some disadvantages. For example, for single-side mounted boards, all components are mounted on the front surface of the board, which makes difficult to decrease the size and dimension of the board. For double-side mounted boards, although proving relatively small size and dimension, grounding and cooling performance are not good enough for radio circuits. For both single-mounted and double-mounted boards, separated EMC cover(s), which is necessary for shielding, increases the weight and cost of a unit consisting of one or more boards. Moreover, in the existing solutions all the components are mounted on one board (either a single-mounted board or a double-mounted board), which leads to less flexibility when meeting failure problem or function/performance upgrade.

It is desired to provide a novel structure in PCBs to at least partly solve the above mentioned problems.

### SUMMARY OF THE INVENTION

To solve the problems in the prior art, one or more apparatus and method embodiments according to the present invention aim to provide a novel stack-up radio module that can be mounted in a main board.

According to an aspect of the present invention, an embodiment of the present invention provides a radio module. The radio module comprises: a top board with all components mounted on a front surface and a metal substrate on a back surface; a bottom board with all components mounted on a front surface and a metal substrate on a back surface, wherein said bottom board is arranged so that said front surface of said bottom board is opposite to said front surface of said top board; at least one shielding board provided between said top board and said bottom board with certain vertical spacing, wherein said top board, said bottom board and said at least one shielding board are arranged to be substantially in alignment in a vertical direction and be fastened with one another, wherein a board-board electrical connection is established at least between said top board and said bottom board.

According to another aspect of the present invention, an embodiment of the present invention provides a device including at least one printed circuit board, wherein at least one radio module according embodiments of the present invention is mounted on the at least one printed circuit board.

According to another aspect of the present invention, an embodiment of the present invention provides a method for manufacturing a radio module. The method comprises: providing a top board with all components mounted on a front surface and a metal substrate on a back surface; providing a bottom board with all components mounted on a front surface and a metal substrate on a back surface, wherein said bottom board is arranged so that said front surface of said bottom board is opposite to said front surface of said top board; providing at least one shielding board provided between said top board and said bottom board with certain vertical spacing, wherein said top board, said bottom board and said at least one shielding board are arranged to be substantially in alignment in a vertical direction and be fastened with one another, wherein a board-board electrical connection is established at least between said top board and said bottom board.

According to one or more embodiments of the present invention, at least one novel stack-up radio module can be mounted on a maim board, which will decrease size and dimension compared with current single-side/double-side mounted radio boards. In addition, such radio modules according to one or more embodiments of the present invention enable modulization design in the demand of different functionality.

### BRIEF DESCRIPTION OF THE DRAWINGS

Inventive features regarded as the characteristics of the present invention are set forth in the appended claims. However, the present invention, its implementation mode, other objectives, features and advantages will be better understood through reading the following detailed description on the exemplary embodiments with reference to the accompanying drawings, where in the drawings:

FIG. 1 is a cross-sectional view showing a radio module with three boards according to an embodiment of the present invention;

FIG. 2a-2b are cross-sectional views showing radio modules with five boards according to another embodiment of the present invention;

FIG. 3a-3c are cross-sectional views showing radio module (s) mounted on a main board with cooling parts assembled, according to an embodiment of the present invention;

FIG. 4 is a flowchart showing a process of an exemplary method for manufacturing a radio module according to an embodiment of the present invention; and

FIG. 5 is a top view showing an exemplary arrangement of a ball grid array type pad of one board in a radio module according to an embodiment of the present invention.

### DETAILED DESCRIPTION OF THE PREFERRED EMBODIMENT

Hereinafter, embodiments of the present invention will be described with reference to the accompanying drawings. In the following description, many specific details are illustrated so as to understand the present invention more comprehensively. However, it is apparent to the skilled in the art that implementation of the present invention may not have these details. Additionally, it should be understood that the present invention is not limited to the particular embodiments as introduced here. On the contrary, any arbitrary combination of the following features and elements may be considered to implement and practice the present invention, regardless of whether they involve different embodiments. Thus, the following aspects, features, embodiments and advantages are only for illustrative purposes, and should not be understood as elements or limitations of the appended claims, unless otherwise explicitly specified in the claims. Throughout the drawings, the same reference numerals are used to refer to the same or similar elements. In the description, the terms “one side/surface”, “the other side/surface”, “top”, “bottom”, “front”, “back” and so on are used to define and/or differentiate elements, but not be construed as limitation to characteristics of those elements.

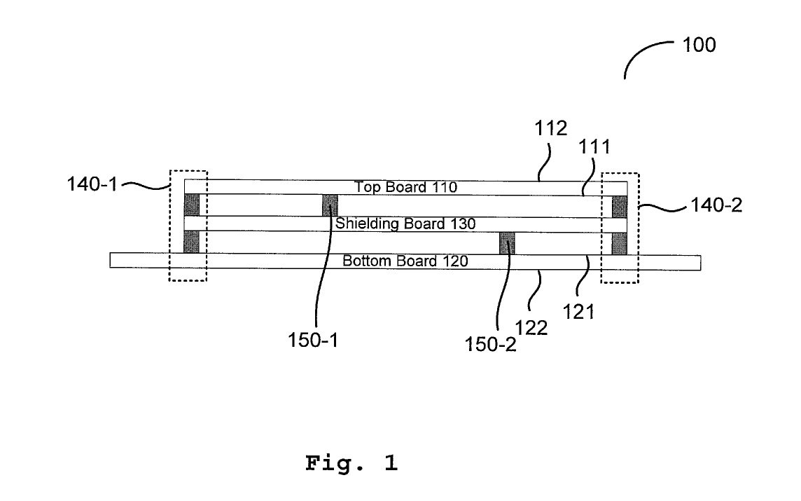

FIG. 1 is a cross-sectional view showing a radio module with three boards according to an embodiment of the present invention.

As shown in FIG. 1, a radio module 100 according to an embodiment of the present invention comprises three boards, i.e., a top board 110, a bottom board 120 and a shielding board 130.

The top board 110 is a single-side mounted board, which has all components including active and passive elements mounted on its front surface 111 and a metal substrate deployed on its back surface 112. Similarly, the bottom board 120 is also a single-side mounted board, which has all components including active and passive elements mounted on its front surface 121 and a metal substrate deployed on its back surface 122. The top and bottom boards are arranged so that their front surfaces (111, 121) with the components can be opposite to each other and their back surfaces (112, 122) with the metal substrates can form at least a part of the outside surface of the radio module 100.

The at least one shielding board, for example the shielding board 130 as shown in FIG. 1, is provided between the top board 110 and the bottom board 120 with certain vertical spacing for component building height. The shielding board 110 is used to provide EMC shielding between the top board 110 and the bottom board 120 and can consist of any kinds of suitable materials for EMC shielding, including, for example but not limited to, foil, sheet metal, metal foam and so on. In an alternative embodiment, the shielding board 130 can be a 2-layer PCB, which has a metal substrate or layer on its back surface.

The top board 110, the bottom board 120 and the shielding board 130 are arranged to be substantially in alignment in a vertical direction and be fastened with one another, which make it possible to decrease total circuitry size in a horizontal direction. A board-board electrical connection is established at least between the top board 110 and the bottom board 120.

The physical fastness and electrical connection between the boards of the radio module 100 can be done in any suitable way in the art.

According to an embodiment of the invention, the radio module may further comprise at least one shielding connector, for example the shielding connectors 140-1, 140-2 as shown in FIG. 1, for establishing the board-board electrical connection; and at least one metal cage (not shown in FIG. 1), provided vertically across edges of respective boards of the radio module, for building up a shielding wall for the radio module 100 together with the at least one shielding connector in the vertical direction. It can be appreciated that the shielding connectors 140-1, 140-2 in this embodiment act as both the fastening and electrical connecting parts for the boards of the radio module 100. And the shielding wall in the vertical direction of the radio module 100 is formed by appropriately assembling the shielding connectors 140-1, 140-2 and the metal cage, which can be any suitable shape to adapt to the number and the arrangement of the connectors equipped in the radio module 100. For example, when only one shielding connector is adopted in one side of the radio module 100, a U-shaped cage can be used to for the shielding wall. In other implementations, a strip-shaped or L-shaped cage can be used to adapt to different arrangement of one or more shielding connectors connecting the boards of the radio module 100.

In some implementations, the shielding board may be adopted to establish the board-board electrical connection for signal transfer. In such implementations, the shielding board 130, which for example is a 2-layer PCB, enables wiring for signal transfer between the top board 110 and the bottom board 120.

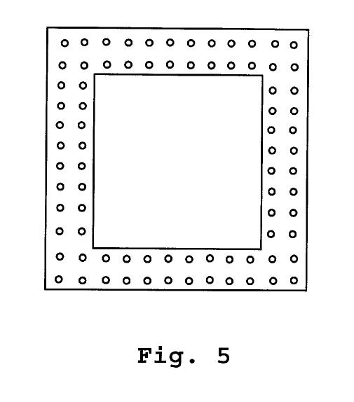

According to an embodiment of the invention, a ball grid array (BGA) (not shown in FIG. 1) can be used to establish said board-board electrical connection and build up a shielding wall for said radio module in the vertical direction. FIG. 5 is a top view showing an exemplary arrangement of a BGA type pad of one board in the radio module. The connected side board need to have an opposite pad (for example, with corresponding bowl shapes) to connected with the BGA type pad.

When the boards of the radio module are assembled together by the BGA, a BGA-type wall built across the edge areas of respective boards of the radio module in the vertical direction will have both signal transmission and shielding functions.

In order to be connected with a main board and/or another radio module, the radio module 100 has connection portions. In the embodiment as shown in FIG. 1, the bottom board 120 has bigger dimension than the other boards in the radio module to form the connection portions for electrical connection with a main board and/or another radio module. For example, PCB-to-PCB connectors with pins (not shown in FIG. 1) can be provided in or form as a part of connection portions so as to conduct signal transmission between the radio module 100 and the main board/the further radio module and EMC function.

In an embodiment of the present invention, the top board 110 or/and the bottom board 120 can be divided into separate shielding cavities within a board via shielding parts including, for example, between-board shielding parts 150-1, 150-2 as shown in FIG. 1 and on-board shielding parts (not shown in FIG. 1) such as metal strips on the front surface (s) of the top board 110 and/or the bottom board 120. The shielding parts 150-1, 150-2 can be embodied by any kinds of suitable materials for EMC shielding. For example, the shielding parts 150-1, 150-2 can be implemented as shielding connectors or by the BGA.

With reference to FIG. 1, a basic structure of the radio module according to an embodiment of the present invention has been described above. However, some variations or modifications can be made based on the structure as shown FIG. 1. For example, the radio module 100 may have more than one shielding board positioned between the top board 110 and the bottom board 120. Those skilled in the art may appreciate that the number of the shielding boards used to provide EMC shielding function will not constitute a limitation to the present invention.

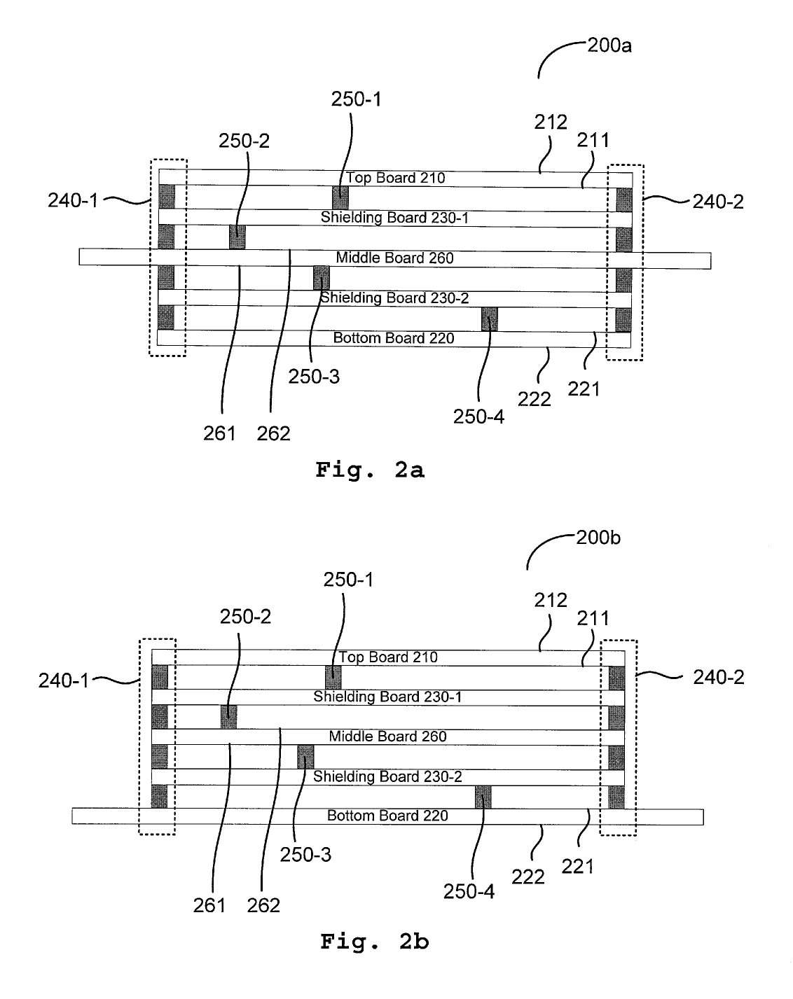

FIGS. 2a and 2b are cross-sectional views showing radio modules with five boards according to another embodiment of the present invention.

As shown in FIGS. 2a and 2b, the radio modules 200a and 200b have a similar stack-up structure with the radio module 100 of FIG. 1. In contrast to the radio module 100, each of the radio modules 200a and 200b further comprises a middle board 260 between the top board 210 and the bottom board 220. A middle board in a radio module according to embodiments of the present invention can be either a single-side mounted board or a double-side mounted board and be arranged so that any surface of the middle board on which the components are mounted is immediately adjacent to a shielding board with certain vertical spacing. As shown in either FIG. 2a or FIG. 2b, the middle board 260 is a double-side mounted board with its two surfaces immediately adjacent to shielding boards 230-1, 230-2 correspondingly. The shielding boards 230-1, 230-2 are used to provide EMC shielding between the top board 210 and the middle board 260 as well as between the middle board 260 and the bottom board 220. The shielding boards 230-1, 230-2 can consist of any kinds of suitable materials for EMC shielding, including, for example but not limited to, foil, sheet metal, metal foam and so on. In an alternative embodiment, the shielding boards 230-1 and 230-2 can be 2-layer PCBs, which has a metal substrate or layer on its back surface.

The top board 210, the bottom board 220, the middle board 260 and the shielding boards 230-1, 230-2 are arranged to be substantially in alignment in a vertical direction and be fastened with one another. A board-board electrical connection is established at least between the top board 210, the bottom board 220 and the middle board 260.

The physical fastness and electrical connection between the boards of the radio module 200a and 200b can be done in any suitable way in the art.

Similar with the radio module 100 as shown in FIG. 1, each of the radio modules 200a and 200b may further comprise at least shielding connectors 240-1, 240-2 for establishing the board-board electrical connection; and at least one metal cage (not shown in FIGS. 2a, 2b), provided vertically across edges of respective boards of the radio module, for building up a shielding wall for the radio module 200a/200b together with the shielding connector 240-1, 240-2 in the vertical direction. It can be appreciated that the shielding connectors 240-1, 240-2 in this embodiment act as both the fastening and electrical connecting parts for the boards of the radio module 200a/200b. And the shielding wall in the vertical direction of the radio module 200a/200b is formed by appropriately assembling the shielding connectors 240-1, 240-2 and the metal cage, which can be any suitable shape to adapt to the number and the arrangement of the connectors equipped in the radio module 200a/200b.

In some implementations, the shielding board 230-1, 230-2 may be adopted to establish the board-board electrical connection for signal transfer. In such implementations, the shielding board 230-1, 230-1, which for example is a 2-layer PCB, enables wiring for signal transfer between the top board 210, the middle board 260 and the bottom board 220.

According to an embodiment of the invention, a ball grid array (BGA) (not shown in FIGS. 2a and 2b) can also be used to establish said board-board electrical connection and build up a shielding wall for said radio module in the vertical direction.

In the embodiment as shown in FIG. 2a, the middle board 260 of the radio module 200a has bigger dimension than the other boards in the radio module to form the connection portions for electrical connection with a main board and/or another radio module, while in the embodiment as shown in FIG. 2b, the bottom board 220 of the radio module 200b has a bigger dimension than the other boards in the radio module to form the connection portions for electrical connection with a main board and/or another radio module. PCB-to-PCB connectors with pins (not shown in FIG. 2a or 2b) can be provided in or form as a part of connection portions so as to conduct signal transmission between the radio module 200a/200b and the main board/the further radio module and EMC function.

As shown in FIGS. 2a and 2b, the top board 210, the middle board 260 and the bottom board 220 can be divided into separate shielding cavities within a board via shielding parts including, for example, between-board shielding parts 250-1, 250-2, 250-3, 250-4 and on-board shielding parts (not shown in FIGS. 2a and 2b) such as metal strips on the front surface (s) of the top board 210, the middle board 260 and the bottom board 220. The shielding parts 250-1, 250-2, 250-3, 250-4 can be embodied by any kinds of suitable materials for EMC shielding. For example, the shielding parts 250-1, 250-2, 250-3, 250-4 can be implemented as shielding connectors or by the BGA.

Although the further embodiments of the present invention have been described in the preceding paragraphs with reference to FIGS. 2a and 2b, it should be appreciated that variations and modifications to the examples given can be made without departing from the scope of the invention as claimed. For example in some embodiments of the invention, the radio module may comprise more than one middle board. If a further middle board is a double-side mounted board, then a further shielding board is also needed to perform EMC shielding. If a further middle board is a single-side mounted board, then in an implementation, there is no need to provide a further shielding board as the metal back surface of the further middle board can act as a shielding board.

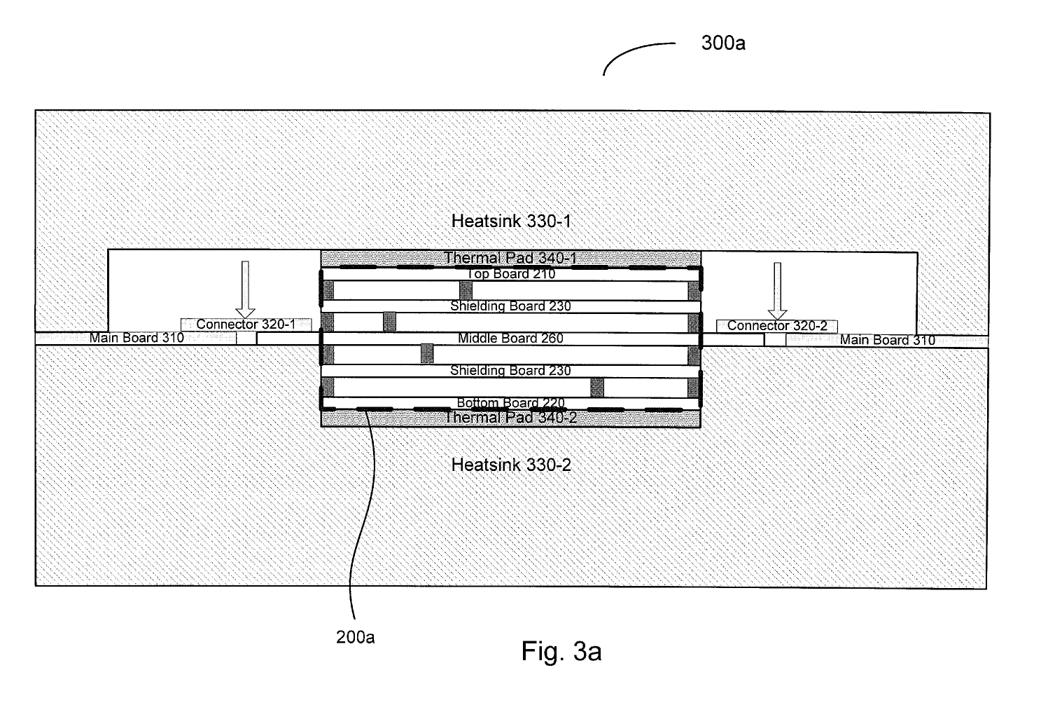

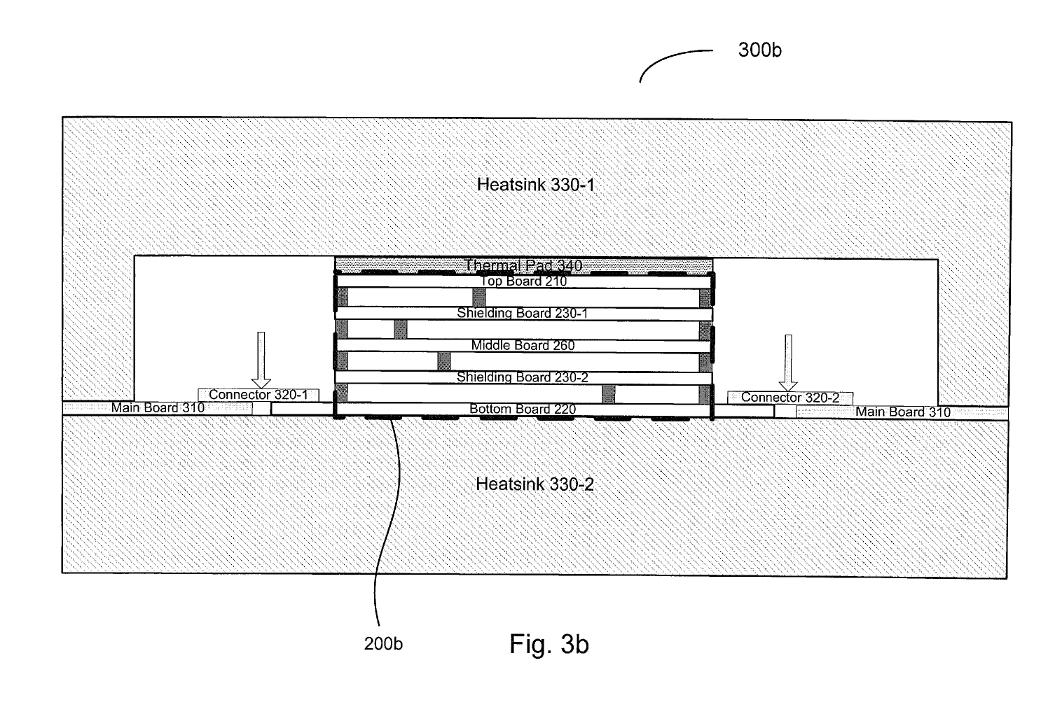

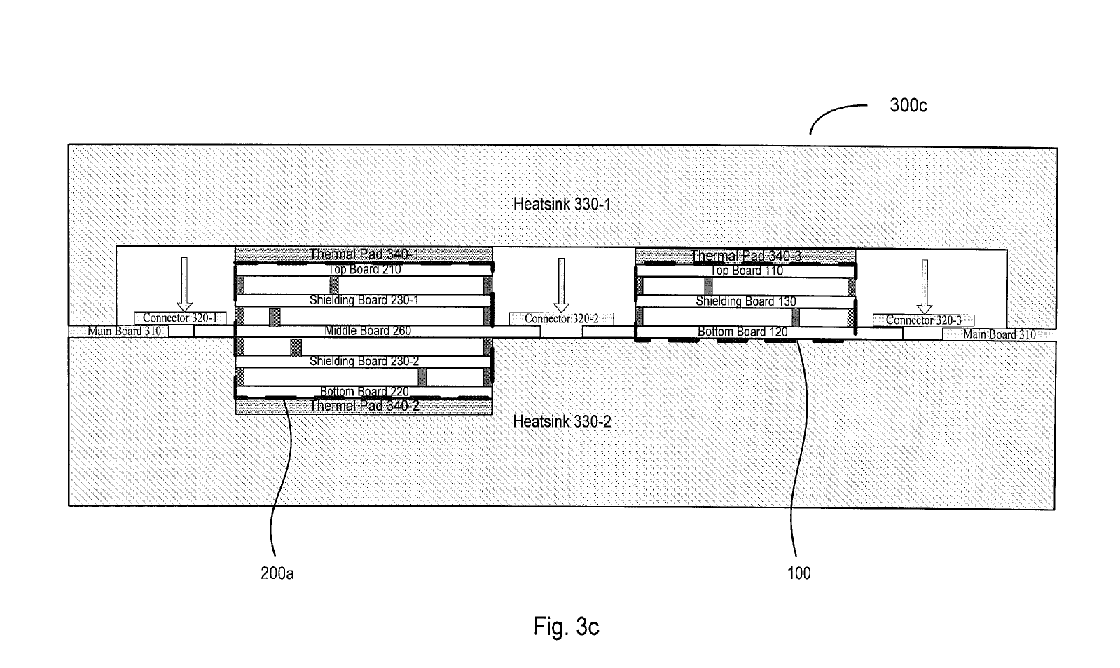

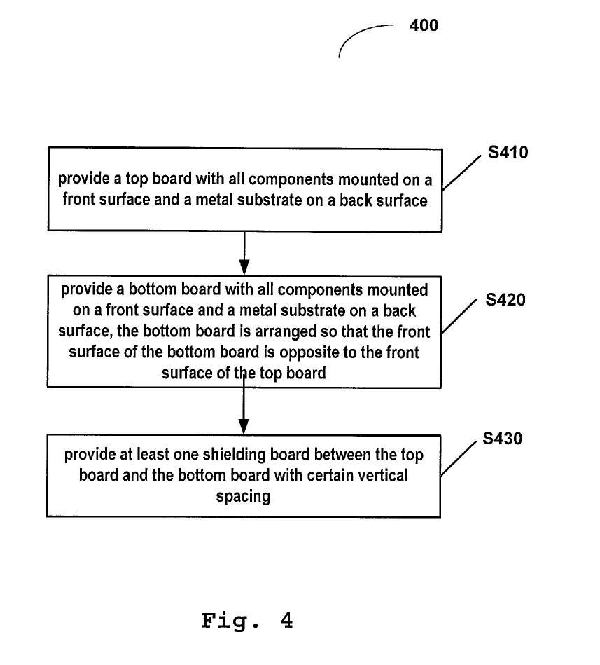

FIG. 3a-3c are cross-sectional views showing radio module (s) mounted on a main board with cooling parts assembled, according to an embodiment of the present invention.

In the embodiment as shown in FIG. 3a, a 5-board radio module, for example, the radio module 200a is mounted on a main board 310. The connection between the radio module 200a and the main board 310 can be done by PCB to PCB connectors 320-1, 320-2 and connecting pads (not shown) on connection portions of the middle board 260 of the radio module 200a and the main board 310.

Cooling parts are used for heat dissipation for the radio module 200a. As shown in FIG. 3a, the back surface of the top board 210 and the back surface of the bottom board 220 are contacted with cooling parts respectively. In this embodiment, the cooling parts may include heatsinks 330-1, 330-2 and optional thermal pads 340-1, 340-2. For the radio module 200a, the thermal pad 340-1 may be needed to guarantee tight contact between the heatsink 330-1 and the back surface 212 of the top board 210 of the radio module 200a. And the thermal pad 340-2 may be needed to guarantee that the heatsink 330-2 can contact tightly with the back surface 222 of the bottom board 220 as well as the connection portion of the middle board 260, of the radio module 220a. The cooling parts, the radio module 200a and the main board 310 can be assembled for example by screw and in an appropriate assembly sequence.

In the embodiment as shown in FIG. 3b, a 5-board radio module, for example, the radio module 200b is mounted on a main board 310. The connection between the radio module 200b and the main board 310 can be done by PCB to PCB connectors 320-1, 320-2 and connecting pads (not shown) on connection portions of the bottom board 220 of the radio module 200b and the main board 310.

Similarly, cooling parts are used for heat dissipation for the radio module 200b. As shown in FIG. 3b, the back surface of the top board 210 and the back surface of the bottom board 220 (including the extended connection portions) are contacted with cooling parts respectively. In this embodiment, the cooling parts may include heatsinks 330-1, 330-2 and an optional thermal pad 340. For the radio module 200b, the thermal pad 340 may be needed to guarantee tight contact between the heatsink 330-1 and the back surface 212 of the top board 210 of the radio module 200b. The cooling parts, the radio module 200b, the main board 310 can be assembled for example by screws and in an appropriate assembly sequence.

In the embodiment as shown in FIG. 3c, a 5-board radio module, for example, the radio module 200a and a 3-board radio module, for example, the radio module 100 are mounted on a main board 310. The connection between the radio module 200a and the main board 310, between the radio module 220a and the radio module 100 as well as between the radio module 100 and the main board 310 can be done by PCB to PCB connectors 320-1, 320-2, 320-3 and connecting pads (not shown) on connection portions of the middle board 220 of the radio module 200a, connection portions of the bottom board 120 of the radio module 100 and the main board 310.

Cooling parts are used for heat dissipation for the radio modules 100 and 200a. As shown in FIG. 3c, the back surface of the top board 210 and the back surface of the bottom board 220 of the radio module 200a are contacted with cooling parts respectively; the back surface 112 of the top board 110 and the back surface 122 of the bottom board 120 of the radio module 100 are contacted with cooling parts respectively. In this embodiment, the cooling parts may include heatsinks 330-1, 330-2 and optional thermal pads 340-1, 340-2, 340-3. For the radio module 200a, the thermal pad 340-1 may be needed to guarantee tight contact between the heatsink 330-1 and the back surface 212 of the top board 210 of the radio module 200a. And the thermal pad 340-2 may be needed to guarantee that the heatsink 330-2 can contact tightly with the back surface 222 of the bottom board 220 as well as the connection portion of the middle board 260, of the radio module 220a. For the radio module 100, the thermal pad 340-3 may be needed to guarantee tight contact between the heatsink 330-1 and the back surface 112 of the top board 110 of the radio module 100. The cooling parts, the radio modules 200a, 100, the main board 310 can be assembled for example by screws and in an appropriate assembly sequence.

It can be seen that both the top board and the bottom board of the radio module can directly contact with cooling parts, which can improve cooling performance of the radio module. From a perspective of circuit designing, in order to take full advantage of this characteristic of the radio module, active components with higher heat dissipation can be arranged on the front surfaces of the top and bottom boards of the radio module to the greatest extent, while for a middle board (if any in the radio module), it is preferred to arrange passive components or active components with less heat dissipation on it.

FIG. 4 is a flowchart showing a processing of an exemplary method 400 for manufacturing a radio module according to an embodiment of the present invention.

In step S410 is provided a top board with all components mounted on a front surface and a metal substrate on a back surface is provided.

In step S420 is provided a bottom board with all components mounted on a front surface and a metal substrate on a back surface. The bottom board is arranged so that the front surface of said bottom board is opposite to said front surface of said top board.

In step S430, at least one shielding board is provided between said top board and said bottom board with certain vertical spacing.

In the radio module manufactured according to the process of FIG. 4, the top board, the bottom board and the at least one shielding board are arranged to be substantially in alignment in a vertical direction and be fastened with one another. A board-board electrical connection is established at least between the top board and the bottom board.

According to an embodiment of the present invention, in a further step (not shown in FIG. 4), at least one middle board with components mounted on a front surface and/or a back surface is provided, wherein the middle board is arranged so that any surface of said middle board on which the components are mounted is immediately adjacent to a shielding board with certain vertical spacing. In this embodiment, the top board, the bottom board, the at least one middle board and the at least one shielding board are arranged to be substantially in alignment in a vertical direction and be fastened with one another. A board-board electrical connection is established at least among the top board, the at least one middle board and the bottom board.

The physical fastness and electrical connection between the boards of the radio module can be done in any suitable way in the art.

According to an embodiment of the present invention, the method for manufacturing a radio module may further comprise following steps (not shown in FIG. 4): providing at least one shielding connector for establishing the board-board electrical connection; providing at least one metal cage vertically across edges of respective boards of the radio module, for building up a shielding wall for the radio module together with the at least one shielding connector in the vertical direction.

According to an alternative embodiment of the present invention, the method for manufacturing a radio module may comprise following steps (not shown in FIG. 4): providing a ball grid array for establishing said board-board electrical connection and building up a shielding wall for said radio module in the vertical direction.

The processing of an exemplary method for manufacturing a radio module according to an embodiment of the present invention has been depicted in detail with reference to FIG. 4. It should be noted that the above depiction is only exemplary, not intended for limiting the present invention. In other embodiments of the present invention, this method may have more, or less, or different steps, and numbering the steps is only for making the depiction more concise and much clearer, but not for stringently limiting the sequence between each steps; while the sequence of steps may be different from the depiction. For example, in some embodiments, the above one or more optional steps may be omitted. Specific embodiment of each step may be different from the depiction. All these variations fall within the spirit and scope of the present invention.

According to embodiments of the present invention, the stack-up radio module mounted on a main board, can be used in any of suitable devices, for example, such as base station devices, network element devices, various consumer electronic products, and so on. The stack-up radio module according to embodiments of the present invention can decrease size and dimension and enable an improved cooling performance compared with current single-side/double-side mounted radio boards. As the radio module provides EMC shielding by itself, no traditional metallic EMC cover is needed, which is cost-saving and will decrease the weight of a device including such stack-up radio module. In addition, such radio modules according to one or more embodiments of the present invention enable modulization design in the demand of different functionality.

The present invention has been specifically illustrated and explained with reference to the preferred embodiments. The skilled in the art should understand various changes thereto in form and details may be made without departing from the spirit and scope of the present invention.

1. A radio module, comprising:
a top board with all components mounted on a front surface and a metal substrate on a back surface;
a bottom board with all components mounted on a front surface and a metal substrate on a back surface, wherein said bottom board is arranged so that said front surface of said bottom board is opposite to said front surface of said top board; and
at least one shielding board provided between said top board and said bottom board with certain vertical spacing,
wherein said top board, said bottom board and said at least one shielding board are arranged to be substantially in alignment in a vertical direction and be fastened with one another,
wherein a board-board electrical connection is established at least between said top board and said bottom board.

2. The radio module according to claim 1, wherein
said bottom board has bigger dimension than the other boards in said radio module to form connection portions for electrical connection with a main board and/or another radio module.

3. The radio module according to claim 1, further comprising:
at least one middle board with components mounted on a front surface and/or a back surface, wherein said middle board is arranged so that any surface of said middle board on which the components are mounted is immediately adjacent to a shielding board with certain vertical spacing,
wherein said top board, said bottom board, said at least one middle board and said at least one shielding board are arranged to be substantially in alignment in a vertical direction and be fastened with one another,
wherein a board-board electrical connection is established at least among said top board, said at least one middle board and said bottom board.

4. The radio module according to claim 3, wherein
one board of said top board, said bottom board and said at least one middle board has bigger dimension than the other boards in said radio module to form connection portions for electrical connection with a main board and/or another radio module.

5. The radio module according to claim 1, comprising:
at least one shielding connector for establishing said board-board electrical connection;
at least one metal cage, provided vertically across edges of respective boards of said radio module, for building up a shielding wall for said radio module together with said at least one shielding connector in the vertical direction.

6. The radio module according to claim 1, comprising:
ball grid array for establishing said board-board electrical connection and building up a shielding wall for said radio module in the vertical direction.

7. The radio module according to claim 1, wherein
said back surface of said top board and said back surface of said bottom board are contacted with cooling parts respectively.

8. The radio module according to claim 1, wherein
at least one of said top board, said bottom board and said at least one middle board is divided into separate shielding cavities within a board via shielding parts.

9. The radio module according to claim 3, wherein
said at least one shielding board is a 2-layer printed circuit board.

10. A device including at least one printed circuit board,
wherein at least one radio module according to claim 1, is mounted on the at least one printed circuit board.

11. A method for manufacturing a radio module, comprising:
providing a top board with all components mounted on a front surface and a metal substrate on a back surface;
providing a bottom board with all components mounted on a front surface and a metal substrate on a back surface, wherein said bottom board is arranged so that said front surface of said bottom board is opposite to said front surface of said top board; and
providing at least one shielding board between said top board and said bottom board with certain vertical spacing,
wherein said top board, said bottom board and said at least one shielding board are arranged to be substantially in alignment in a vertical direction and be fastened with one another,
wherein a board-board electrical connection is established at least between said top board and said bottom board.

12. The method according to claim 11, further comprising:
providing at least one middle board with components mounted on a front surface and/or a back surface, wherein said middle board is arranged so that any surface of said middle board on which the components are mounted is immediately adjacent to a shielding board with certain vertical spacing,
wherein said top board, said bottom board, said at least one middle board and said at least one shielding board are arranged to be substantially in alignment in a vertical direction and be fastened with one another,
wherein a board-board electrical connection is established at least among said top board, said at least one middle board and said bottom board.

13. The method according to claim 11, comprising:
providing at least one shielding connector for establishing said board-board electrical connection;
providing at least one metal cage vertically across edges of respective boards of said radio module, for building up a shielding wall for said radio module together with said at least one shielding connector in the vertical direction.

14. The method according to claim 1, comprising:
providing ball grid array for establishing said board-board electrical connection and building up a shielding wall for said radio module in the vertical direction.
